(19) United States
(12) Patent Application Publication
(10) Pub. No.: US 2025/0119095 A1
(43) Pub. Date: Apr. 10, 2025

(54) OUTPUT LINE CONNECTION STRUCTURE FOR SOLAR CELL MODULE

(71) Applicant: SHARP KABUSHIKI KAISHA, Sakai City, Osaka (JP)

(72) Inventor: Yasushi YOSHIKAWA FUNAKOSHI, Sakai City, Osaka (JP)

(21) Appl. No.: 18/836,092

(22) PCT Filed: Aug. 22, 2023
(86) PCT No.: PCT/JP2023/030087

§ 371 Date: Aug. 6, 2024

(30) Foreign Application Priority Data
Sep. 12, 2022 (JP) 2022-144526

(51) Int. Cl. H02S 40/36; H01R 4/48

(52) U.S. Cl. CPC H02S 40/36; H01R 4/48

(57) ABSTRACT

A solar cell module includes an output lead that is provided correspondingly to a solar cell string in which a plurality of solar cells is connected in series with each other. The output lead is drawn out from a back surface side of the solar cell module. An external connection cable has a connecting end to be connected to the output lead, and is provided with a connection terminal at the connecting end. The connection terminal is provided with a holder part into which the output lead is inserted. The holder part and an extreme end of the output lead are connected together. The external connection cable is arranged on the back surface side of the solar cell module, and a second end of the external connection cable is connected to an external electronic device, etc.

### TECHNICAL FIELD

The present disclosure relates to an output line connection structure for a solar cell module.

### BACKGROUND ART

To generate photovoltaic power, a widely known photovoltaic system employs a plurality of solar cell modules fixedly installed on a roof or a roof terrace of a building, or on the ground, etc. A typical solar cell module includes a plurality of substantially rectangular solar cells disposed between a transparent substrate and a back sheet, with an output lead being provided on each solar cell string (connection unit) and drawn out to a back surface side of the solar cell module that is opposite to its light-receiving surface.

In a conventional photovoltaic system as exemplified in FIG. 13, output leads 92 are drawn out from a slit 91 formed in a back surface 902 side of a solar cell module 90, and a terminal box 93 is attached to the output leads 92 so as to extract an output of the solar cell module 90. The terminal box 93 of this type typically contains bypass diodes. External connection cables 94, each having a connector 95 at an extreme end thereof, extend from the terminal box 93 and serve to connect the solar cell module with another adjacent solar cell module or an external device (see, for example, PTL 1).

### PRIOR ART DOCUMENTS

### Patent Documents

PTL 1: JP 2000-357812 A

### SUMMARY OF INVENTION

### Technical Problem

Recently, applications of the photovoltaic system are not limited to construction of a photovoltaic system in which solar cell modules are fixed on a building or on the ground. For the photovoltaic system capable of converting light energy to electrical energy, various applications have been under development, including installation of solar cell modules on a body surface of an automobile or the like, and use of solar cell modules as a power source for a small electronic device such as a mobile terminal.

In such cases, unlike the conventional photovoltaic system described earlier, a device connected to the solar cell module is positioned on a back surface side of the solar cell module, and hence the space on the back surface side of the solar cell module is limited. Besides, since such a photovoltaic system is not expected to have a service life of as long as about several decades, relatively thinly coated typical electric cables, rather than a conventional terminal box or thickly coated long-term weatherable external connection cables, may be used to connect output leads of the solar cell module to an electric component, battery, or the like. Nevertheless, the connection between the output leads and the electric cables requires direct solder connection between the electric cables and the respective output leads, which disadvantageously complicates the connection operation. Besides, direct solder connection between the electric cables and the output leads may induce an operational error and may degrade connection reliability.

The present disclosure has been made in view of the above-described circumstances, and an object of the present disclosure is to provide an output line connection structure for a solar cell module that can facilitate a connection operation via external connection cables and that is highly reliable.

### Solution to Problem

According to the present disclosure, a solution for achieving the above-mentioned object provides an output line connection structure for a solar cell module, for connecting an output line that extends out of the solar cell module, with an external connection cable. The solar cell module includes at least one solar cell string in which a plurality of solar cells is connected in series with each other. The output line is provided correspondingly to the solar cell string and is drawn out from a back surface of the solar cell module, the back surface being a surface opposite to a light-receiving surface of the solar cell module. The external connection cable has a connecting end to be connected to the output line and includes a connection terminal at the connecting end, the connection terminal being provided with a holder part into which the output line is inserted. A connecting portion for the holder part and an extreme end of the output line is provided on a back surface side of the solar cell module. The external connection cable is arranged on the back surface side of the solar cell module and has a second end that is an end opposite to the connecting end of the external connection cable. The second end of the external connection cable is connected to an external electronic device or a terminal box.

Preferably in the output line connection structure for a solar cell module, the output line is a band-like conductor plate; the holder part has a tubular shape with a clearance; and the extreme end of the output line is inserted in and crimped on the holder part.

Further in the output line connection structure for a solar cell module, the output line may have a tapered portion narrowing toward the extreme end.

Further in the output line connection structure for a solar cell module, the holder part may have a tubular shape with a clearance; the extreme end of the output line may have a tubular shape narrowing toward an extremity thereof and insertable in the holder part; and the extreme end of the output line may be inserted in and crimped on the holder part.

Further in the output line connection structure for a solar cell module, the output line connection structure may include an elastic contact piece provided inside the holder part and configured to hold the output line in a pinched manner.

Further in the output line connection structure for a solar cell module, the output line may include a bent portion that is a turned-back portion of the extreme end, and the bent portion may be engaged with the elastic contact piece.

Further in the output line connection structure for a solar cell module, the solar cell string may include a plurality of groups of solar cells in each of which a plurality of solar cells adjacent in a first direction is connected in series with each other, and an output wiring member that connects ends of the groups of solar cells may be provided along a second direction that is orthogonal to the first direction. An end of the output wiring member may be drawn out to the back surface side, either along the first direction or along the second direction, to serve as the output line.

### Advantageous Effect of Invention

The present disclosure can facilitate a connection operation in a solar cell module via external connection cables, and can also enhance connection reliability.

### BRIEF DESCRIPTION OF DRAWINGS

FIG. 1 is a plan view of a back surface side of a solar cell module, showing a main part of an output line connection structure for a solar cell module according to Embodiment 1 of the present disclosure.

FIG. 2 is a perspective view showing output leads and external connection cables of the solar cell module, before the output leads and the external connection cables are connected to each other.

FIG. 3 is a perspective view showing an example of the solar cell module.

FIG. 4 is a partially enlarged view showing another configuration example of the output lead.

FIG. 5 is a perspective view showing an example of a connecting end of the external connection cable.

FIG. 6 is a perspective view showing a connecting end of the external connection cable, in an output line connection structure for a solar cell module according to Embodiment 2 of the present disclosure.

FIG. 7 is a perspective view showing an example of an extreme end of the output lead corresponding to the external connection cable.

FIG. 8 is a schematic plan view showing a part of an output line connection structure for a solar cell module according to Embodiment 3 of the present disclosure, as seen from a back surface side of the solar cell module.

FIG. 9 is a schematic plan view showing an output line connection structure for a solar cell module according to Embodiment 4 of the present disclosure, as seen from a back surface side of the solar cell module.

FIG. 10 is a sectional view showing a connection terminal in an output line connection structure for a solar cell module according to Embodiment 5 of the present disclosure.

FIG. 11 is a sectional view showing another example of the connection terminal.

FIG. 12 is a sectional view showing an output lead connected to the connection terminal.

FIG. 13 is a perspective view showing a conventional output line connection structure for a solar cell module.

### DESCRIPTION OF EMBODIMENTS

Output line connection structures for a solar cell module according to the embodiments of the present disclosure are hereinafter described with reference to the drawings. In following Embodiments 1 to 5, common components are represented by common reference signs to omit repetitive description.

### Embodiment 1

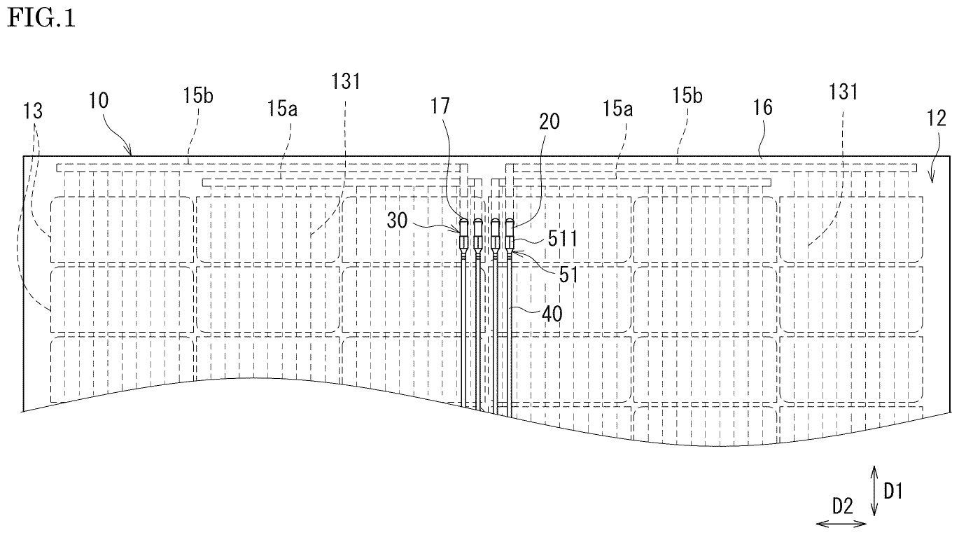

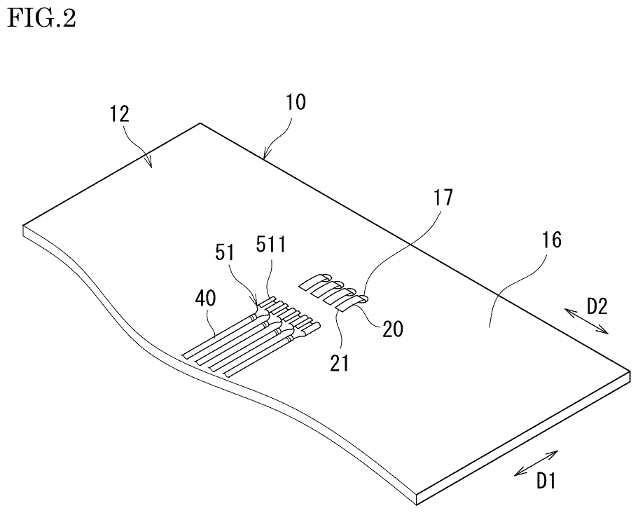

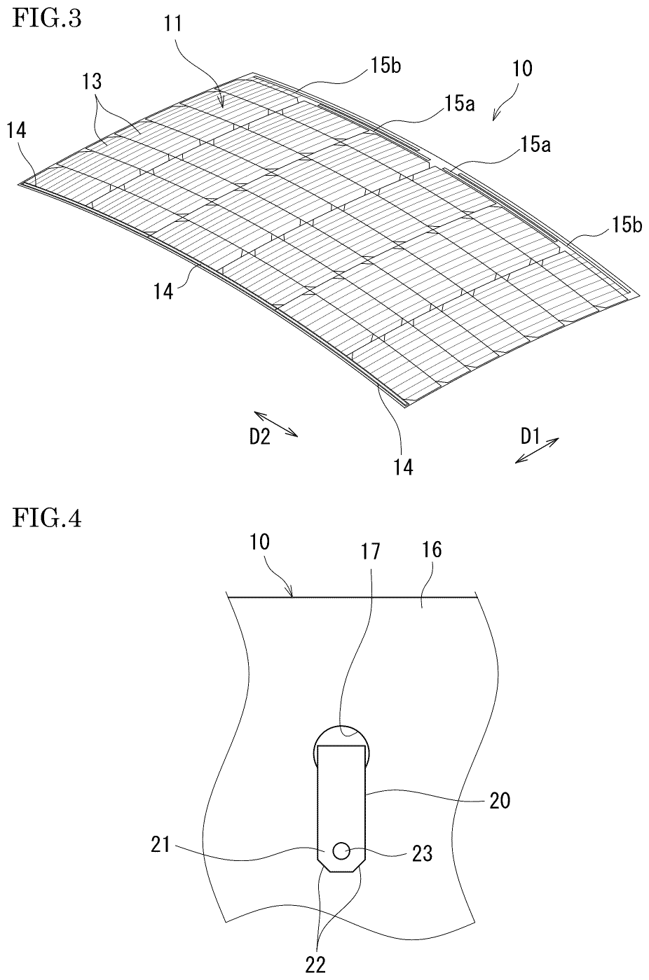

FIG. 1 is a plan view showing an output line connection structure for a solar cell module 10 according to Embodiment 1 of the present disclosure. FIG. 2 is a perspective view showing output leads 20 and external connection cables 40 of the solar cell module 10, before the output leads 20 and the external connection cables 40 are connected to each other. FIG. 3 is a perspective view showing an example of the solar cell module 10 to which the output line connection structure of the present disclosure is applied.

Note that FIG. 1 shows a back surface 12 side of the solar cell module 10. Solar cells 13, output wiring members 15a, 15b, and some other components are shown by dashed lines because these components are covered by a back sheet 16 that constitutes the back surface 12 and invisible from the back surface 12 side. FIG. 3 shows a light-receiving surface 11 side of the solar cell module 10, omitting a resin layer, a transparent substrate, and other components provided in the solar cell module 10. In the following description of the solar cell module 10, the light-receiving surface 11 means a surface on which the sunlight is mainly incident, and the back surface 12 means a surface opposite to the light-receiving surface.

As shown in FIG. 3, the solar cell module 10 according to the illustrated configuration includes, among other components, a plurality of solar cells 13 and a plurality of wiring members (14, 15) mutually connecting the solar cells 13 that are connected in series with each other. These components are sealed between a transparent substrate on the light-receiving surface 11 side and the back sheet 16 on the back surface 12 side (see FIG. 1).

In this illustrated configuration, the solar cell module 10 includes solar cell strings. In each solar cell string, adjacent solar cells 13 are connected in series in a first direction DI by wiring members 131 such that a plurality of solar cells 13 is arranged in a line. The solar cells 13 are flat plate-like photovoltaic elements that generate electric power in response to light irradiation. The solar cells 13 adjacent in the first direction D1 are connected in series with each other. For example, in order to make the solar cell module 10 mountable on a vehicle roof, the solar cell module 10 as a whole may have a curved shape that is bent in the first direction D1 and in a second direction D2, and the solar cells 13 may be arranged along the curved shape.

The plurality of solar cells 13 is linearly arranged in the first direction D1 and connected in series with each other to form a solar cell string. For two solar cell strings that are adjacent in the second direction D2, the solar cells 13 at a first end in the first direction DI are connected in series with each other via a relay wiring member 14, and the solar cells 13 at a second end in the first direction D1 are connected in series with each other via the output wiring member 15a. All of the plurality of solar cells 13 in the solar cell module 10 are thus connected in series.

Output wiring members 15a, 15b (for example, a total of four output wiring members) are provided along the second end in the first direction D1 so as to establish electrical connection with the external connection cables 40. The surface of the output wiring members 15a, 15b may be covered by an insulating member such as an insulating film. Each of the output wiring members 15a also functions to connect two adjacent solar cell strings in series. The output wiring member 15b at one end is electrically connected to the solar cell strings on a high-potential side in the second direction D2, and the output wiring member 15b at the other end is electrically connected to the solar cell strings on a low-potential side in the second direction D2.

Each of the output wiring members 15a, 15b has an end thereof located at a substantial middle part in the second direction D2 of the solar cell module 10. As shown in FIG. 2, such ends of the output wiring members 15a, 15b are drawn out through respective through-holes 17 formed in the back sheet 16, to the back surface 12 side of the solar cell module 10, and serve as output leads (output lines) 20 for external connection. Accordingly, four tab-like output leads 20 shown in FIG. 2 are provided correspondingly to the respective solar cell strings. The output leads 20 extending outward to the back surface 12 side are connected to first ends (connecting ends) of the external connection cables 40. Second ends of the external connection cables 40, which are opposite to the connecting ends, are connected to an external electronic device (such as an electrical component) or a terminal box.

Each output lead 20 is a band-like conductor plate. For example, the output lead 20 is a band-like wiring member (a bus bar) made of an elongated ribbon-like (or strip-like) substrate whose outer surface is coated with a conductive adhesive or coated by soldering. The material for the substrate is not particularly limited and, for example, may be a metal such as copper.

As shown in FIG. 2, each of the external connection cables 40 has a connection terminal 51 at the connecting end to the output lead 20. The external connection cables 40 are electric cables that are connectable to an electronic device (such as an electrical component or a battery) or a terminal box to be connected to the solar cell module 10. Each of the connection terminals 51 is a metallic terminal connected to a core (not shown) of the external connection cable 40. The electric cable may be, for example, an insulating coated cable whose core has a cross-sectional area of 2 sq (square millimeters by JIS, or AWG 14 by UL standards). Various electric cables are applicable according to the current value.

Each connection terminal 51 has a holder part 511 into which the output lead 20 is inserted. The holder part 511 is integrally provided at an extreme end of the connection terminal 51 and has a deformable, tubular or substantially tubular shape.

An extreme end 21 of each output lead 20 is inserted into the holder part 511 of the external connection cable 40 routed to the back surface 12 of the solar cell module 10. As shown in FIG. 1, the output leads 20 are armored by the holder parts 511, and connecting portions 30 for the holder parts 511 and the output leads 20 are provided on the back surface 12 side of the solar cell module 10. Preferably, the connecting portions 30, the output leads 20, and the through-holes 17 are insulated by application of an insulating film (tape) or by coating with an insulating resin such as silicone.

FIG. 4 is a partially enlarged view showing another configuration example of the output lead 20. On the back surface 12 side of the solar cell module 10, as shown, the extreme end 21 of the output lead 20 is drawn out from the through-hole 17 formed in the back sheet (back surface protection sheet) 16. The shape of the output lead 20 is not limited to a rectangular band-like shape. Alternatively, the output lead 20 may have a tapered portion 22 narrowing toward its extremity. This shape assists insertion of the extreme end 21 of the output lead 20 into the holder part 511 of the connection terminal 51, and facilitates the connection operation.

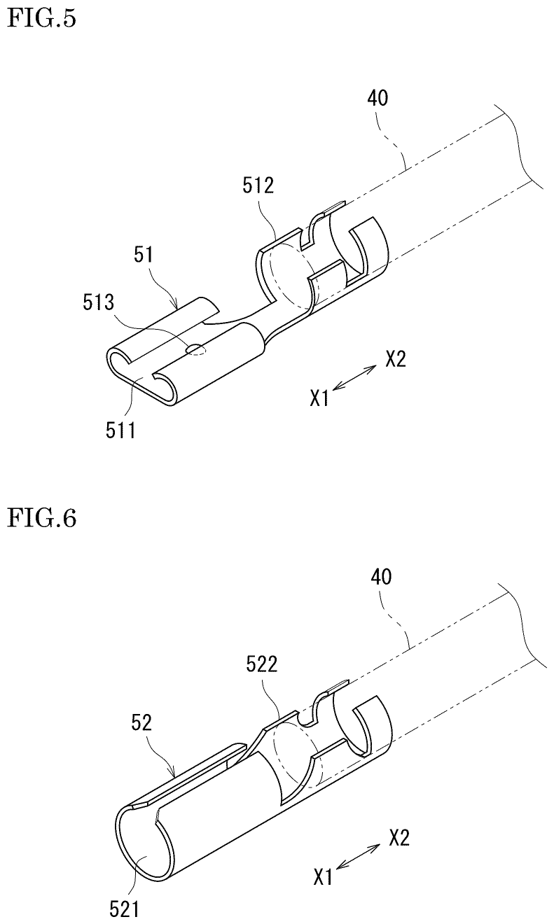

FIG. 5 is a perspective view showing an example of the connecting end of the external connection cable 40. The connection terminal 51 shown in FIG. 5 has the holder part 511 at a first end thereof (an X1 side in the figure) and a fixing part 512 at a second end thereof (an X2 side in the figure). The holder part 511 allows insertion of the output lead 20, and the core of the external connection cable 40 is crimped on the fixing part 512.

The holder part 511 is integrally formed at the first end of the connection terminal 51 and has a tubular or substantially tubular shape. The output lead 20 is inserted inside the holder part 511. In the configuration shown in FIG. 5, the holder part 511 is formed into a tubular or substantially tubular shape by having its widthwise lateral edges bent in a curved shape to form a pair of holder pieces, the pair of holder pieces being opposed to each other with a clearance (a slit) therebetween and each having a substantial horseshoe shape. After the extreme end 21 of the output lead 20 is directly inserted into the holder part 511, the above-described shape allows the holder part 511 to be bent and deformed further, to be crimped on the extreme end 21, and to constitute the connecting portion 30 eventually. A connection hole 23 may be formed approximately in a middle of the extreme end 21 of the output lead 20, allowing connection of the extreme end 21 of the output lead 20 to a protrusion 513 of the holder part 511. Further, the extreme end 21 of the output lead 20 and the holder part 511 may be fixedly connected by soldering.

The connection terminal 51 may be a flat terminal (for example, a type 250, flat female terminal) or the like. For such a flat terminal, the output lead 20 may have any shape as far as its width, thickness, and any other dimension correspond to those of the flat terminal; the output lead 20 may have the tab-like (or band-like) shape as illustrated in FIG. 2 or may have the tapered portion 22 as illustrated in FIG. 4.

In the illustrated configuration, the holder parts 511 and the extreme ends 21 of the output leads 20 are connected at the connecting portions 30, and the connecting portions 30 and the external connection cables 40 are disposed on the back surface 12 side of the solar cell module 10. This configuration can connect the output leads 20 to the terminal box, not directly but via the external connection cables 40. As a result, this configuration allows the output leads 20 and the terminal box to be positioned with a distance from each other, and remarkably improves the degree of freedom as to where bypass diodes (the terminal box) should be installed.

For example, when the solar cell module 10 is installed on a vehicle or an electronic device, the installation space on the back surface side of the solar cell module is often limited. The structure disclosed herein, which can set the position of the terminal box freely, is highly useful in this situation. It is also conceivable that installable positions of the terminal box may be different among various electronic devices. Irrespective of the types of electronic devices on which the solar cell module is installed, the structure disclosed herein can apply the common solar cell module structure up to the output leads 20, and can thereby reduce the production cost.

In addition, when the external connection cables 40 are connected to the terminal box containing the bypass diodes, the structure disclosed herein can use the above-mentioned electric cables as the external connection cables to be led out from the terminal box, thereby facilitating the connection with an electronic device.

The structure of Embodiment 1 is supposed to connect the output leads 20 to the bypass diodes. A more simplified system may use, for example, only the output leads 20 connected to the two output wiring members 15b, thereby extracting the output via the external connection cables 40, converting the voltage by a power converter such as a DC/DC converter, charging a battery or the like, and using the same as a power source. This configuration can omit the terminal box and can reduce both the installation space and the cost.

Further, this structure can establish connection of the output leads 20 with the external connection cables 40 simply by insertion of the extreme ends 21 of the output leads 20 into the connection terminals 51, and thus can ensure a simple error-free operation. Furthermore, this structure offers improved connection reliability by crimping the extreme ends 21 on the connection terminals 51 and thereby preventing the extreme ends 21 from slipping out.

Additionally, in the output line connection structure for the solar cell module 10 according to the present disclosure, the solar cell module 10 is not limited to the configuration illustrated in FIG. 3, etc., but may be any configuration. The number of output leads 20 drawn out of the solar cell module 10 is optional and not limited to four. The draw-out position of the output leads 20 is optional and not limited to the illustrated position. Further, the draw-out position may be provided at more than one location.

### Embodiment 2

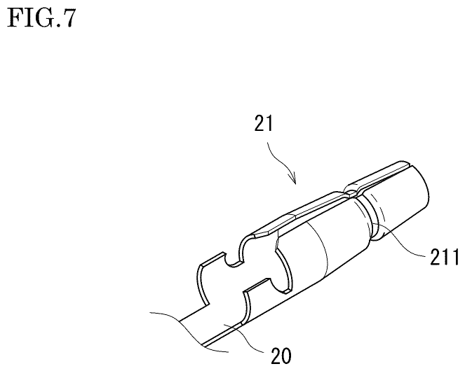

In the present disclosure, the output line connection structure for the solar cell module 10 is not limited to the one disclosed in Embodiment 1. Alternatively, the connecting ends of the external connection cables 40 and the extreme ends of the output leads 20 may be configured, for example, as shown in FIG. 6 and FIG. 7. In the following description, the basic configuration of the solar cell module 10 is common to the one described in Embodiment 1, and the same reference signs are used to omit repetitive description.

FIG. 6 is a perspective view showing another example of the connecting end of the external connection cable 40. FIG. 7 is a perspective view showing a shape of the extreme end of the output lead 20 that corresponds to the external connection cable 40 shown in FIG. 6.

As shown in FIG. 6, a holder part 521 of a connection terminal 52 may be formed like a female bullet terminal composed of a pair of holder pieces, the pair of holder pieces being opposed to each other with a clearance therebetween to define a cylindrical or substantially cylindrical shape. The connection terminal 52 has a cylindrical or substantially cylindrical holder part 521 at a first end on an X1 side thereof and a fixing part 522 at a second end on an X2 side thereof. The holder part 521 allows insertion of the output lead 20, and the core of the external connection cable 40 is crimped on the fixing part 522. The connection terminal 52 may be a female bullet terminal (for example, CB104, JIS standard) or the like.

The holder part 521 of the connection terminal 52 is shaped to engage with an extreme end 21a of the output lead 20 when the extreme end 21a is inserted. Preferably, the extreme end 21a of the output lead 20 is formed like a male bullet terminal as shown in FIG. 7. The extreme end 21a has a tubular shape narrowing toward the extreme end, and has a circumferential groove 211 in an outer peripheral surface thereof. The length, outer diameter, and other dimensions of the extreme end 21a are designed to correspond to those of the holder part 521. When the male bullet terminal-like extreme end 21 of the output lead 20 is inserted into the female bullet terminal-like holder part 521 of the connection terminal 52, these parts are mechanically fixed and electrically connected.

Also in the case of the holder part 521 having the above-described shape, the extreme end 21 of the output lead 20 is directly inserted in and crimped on the holder part 521, and may be fixedly connected further by soldering.

Also in this embodiment, the holder parts 521 of the connection terminals 52 and the extreme ends 21 of the output leads 20 are connected at the connecting portions 30, and the connecting portions 30 and the external connection cables 40 are disposed on the back surface 12 side of the solar cell module 10. Accordingly, this configuration can connect the output leads 20 to the terminal box, not directly but via the external connection cables 40. Similar to the configuration in Embodiment 1, this configuration can improve the degree of freedom as to where bypass diodes (the terminal box) should be installed. Additionally, a more simplified system may use, for example, only the output leads 20 connected to the two output wiring members 15b, thereby extracting the output via the external connection cables 40, converting the voltage by a power converter such as a DC/DC converter, charging a battery or the like, and using the same as a power source.

### Embodiment 3

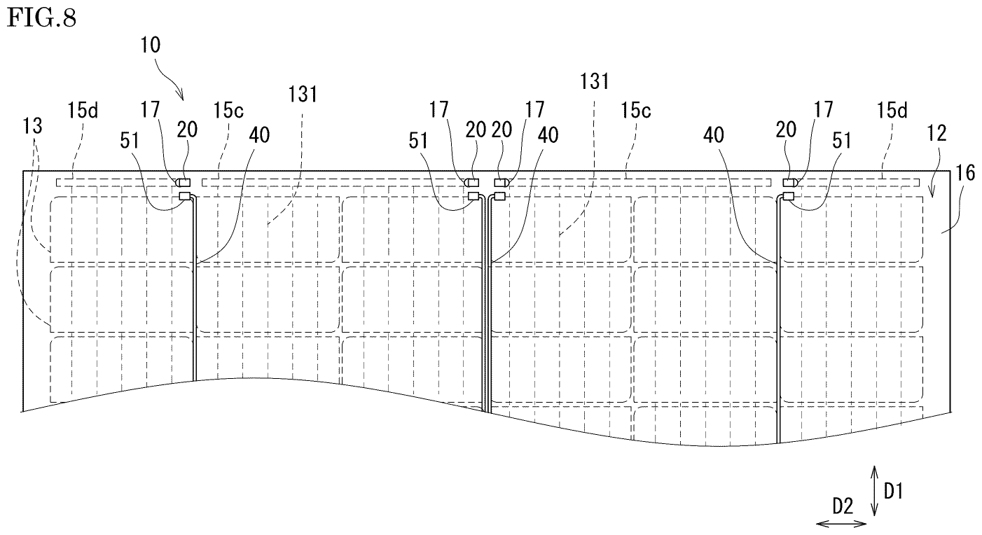

In the present disclosure, the output line connection structure for the solar cell module 10 is not limited to the one disclosed in Embodiment 1, but may be configured, for example, as shown in FIG. 8.

FIG. 8 is a plan view showing an output line connection structure for a solar cell module 10 according to Embodiment 3 of the present disclosure, as seen from a back surface 12 side of the solar cell module 10. In FIG. 8, the solar cells 13, output wiring members 15c, and some other components are shown by dashed lines because these components are covered by the back sheet 16 that constitutes the back surface 12 and invisible from the back surface 12 side.

The solar cells 13 are mutually connected in series in the first direction DI by the wiring members 131 such that a plurality of solar cells 13 is arranged in a line to form a group of series-connected solar cells 13. Output wiring members 15c, 15d are provided along an end of the group of solar cells 13. The output wiring members 15c, 15d are arranged in the second direction D2, and have either one of their opposite ends drawn out through the through-holes 17 to the back surface 12 side of the solar cell module 10 so as to establish electrical connection with the external connection cables 40. Each of the output wiring members 15c functions to connect two adjacent groups of solar cells 13 in series. Each of the output wiring members 15d functions to extract the output of the solar cell module 10 to the outside.

As shown in FIG. 8, the output wiring members 15c and the output wiring members 15d are drawn out through the through-holes 17 to the back surface 12 side, with their orientation unchanged and kept in a routing direction that extends along the second direction D2. The drawn-out output wiring members 15c, 15d serve as the output leads (output lines) 20 for external connection. The output leads 20 extending outward to the back surface 12 side are connected to the connection terminals 51 of the external connection cables 40 to be connected to an electrical component, etc.

As described, when the output wiring members 15c, 15d are drawn out to the back surface 12, the orientation of the output wiring members 15c, 15d is unchanged and kept along the routing direction. This allows the output wiring members 15c, 15d to serve as the output leads 20 without subjecting the ends of the output wiring members 15c, 15d to any processing. This configuration can save an extra connection processing for directing the output wiring members like an L-shape to the first direction D1, can simplify operational steps, and can enhance work efficiency.

### Embodiment 4

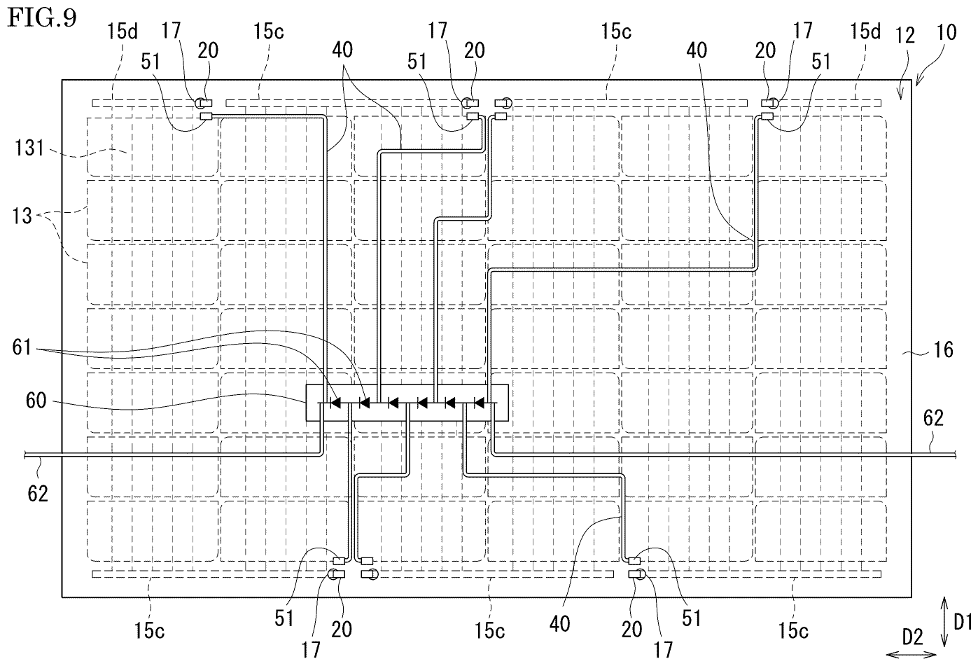

FIG. 9 is a plan view showing an output line connection structure for a solar cell module 10 according to Embodiment 4, as seen from a back surface 12 side of the solar cell module 10. In FIG. 9, the solar cells 13, the output wiring members 15c, 15d, and some other components are shown by dashed lines because these components are covered by the back sheet 16 that constitutes the back surface 12 and invisible from the back surface 12 side.

The output line connection structure for the solar cell module 10 may be configured further as shown in FIG. 9. Also in the solar cell module 10 shown in FIG. 9, the output wiring members 15c, 15d are drawn out through the through-holes 17 to the back surface 12 side, with their orientation unchanged and kept in the routing direction that extends along the second direction. The drawn-out output wiring members 15c, 15d serve as the output leads (output lines) 20 for external connection.

A terminal box 60, shown in FIG. 9 in a simplified manner, is attached to the back sheet 16 on the back surface 12. The terminal box 60 includes a plurality of terminal sections to be connected with the terminals of the external connection cables 40, and bypass diodes 61 connected to the terminal sections. In the illustrated configuration, the terminal box 60 contains six bypass diodes 61. Among the plurality of terminal sections, those on both ends are further provided with external output cables 62 for extracting the output of the solar cell module 10.

In the solar cell module 10 shown in FIG. 9, seven solar cells 13 are arranged in the first direction D1 and connected in series by the wiring members 131, and thereby form a line of a group of solar cells 13. In the illustrated configuration, six lines of the groups of series-connected solar cells 13 are arranged in the second direction D2.

The group of solar cells 13 on each end in the second direction D2 has a following connection structure: at a first end in the direction D1 (an upper end in the figure), the group of solar cells 13 is connected to the output wiring member 15d; at a second end thereof, the group of solar cells 13 is connected in series with an adjacent line of another group of solar cells 13 by the output wiring member 15c. Each output wiring member 15d is connected to the external output cable 62 of the terminal box 60 via the external connection cable 40, and also serves to extract the output of the solar cell module 10. The other output wiring members 15c connect the other adjacent lines of the groups of solar cells 13 in series with each other. The solar cell module 10 thus holds solar cell strings in which a total of 42 (forty-two) solar cells 13 are connected in series in 7×6 arrangement.

According to this arrangement, each line of a group of solar cells 13 is composed of seven solar cells 13, and has its starting end and its terminal end connected in parallel with the bypass diode 61 via the output lead 20 and the external connection cable 40. In this circuit configuration, the solar cell module 10 includes six groups of solar cells 13 arranged in the second direction D2, and each line of the group of solar cells 13 is connected in parallel with corresponding one of the bypass diodes 61 in the terminal box 60.

As mentioned above, the solar cell module 10 used as a power source for a vehicle or a mobile device is more susceptible to shadow or shade than the solar cell module as fixedly installed. The solar cell module 10 shown in FIG. 9 is configured to cope with this situation. When the power generation state of the solar cell module 10 is normal, no electric current flows through the bypass diode 43. However, when a part of the solar cells 13 is in the shadow/shade of a certain structure or the like, the solar cell module does not generate a sufficient power. Then, the shadowed/shaded solar cells 13 act as resistance elements to activate the bypass diode 43, so that the line of the group of solar cells 13 including the shadowed/shaded solar cells 13 can be bypassed. In this situation, the line that includes the shadowed/shaded solar cells 13 is the only line that suffers from power generation loss, and the other five lines of the groups of the solar cells 13 are not affected by shadow or shade. Compared with the case where two lines are connected in parallel with the bypass diode, this configuration can minimize the decrease in the amount of generated power.

In this case, the output leads 20 are drawn out to the back surface 12 side and connected to the terminal box 60 on the back surface 12 via the external connection cables 40. Hence, this configuration can increase the number of bypass diodes without complicating internal wiring in the solar cell module 10 and can still ensure an easy wiring operation. Besides, the wiring in the solar cell module 10 does not require overlayed connection between the solar cells 13 and the output wiring members 15c, 15d, which can prevent cracking and other damages in the solar cells 13. As mentioned above, since the output leads 20 drawn out to the back surface 12 side can be easily connected with the external connection cables 40, this configuration can ensure a simple connection operation and enhance work efficiency even in the presence of a large number of connecting portions.

Note that the number of solar cells 13 contained in each line of the group of solar cells 13 should not be limited to seven, as exemplified, but may be less to provide a smaller unit or may be optional. In addition, the total number of solar cells 13 (the number of serial connections) that constitute the solar cell module 10 is not limited to the illustrated configuration.

### Embodiment 5

In the present disclosure, the output line connection structure for the solar cell module 10 is not limited to the configurations described in Embodiments 1 to 4 above. Additionally, the connection terminal 51 of the external connection cable 40 may be configured as described below.

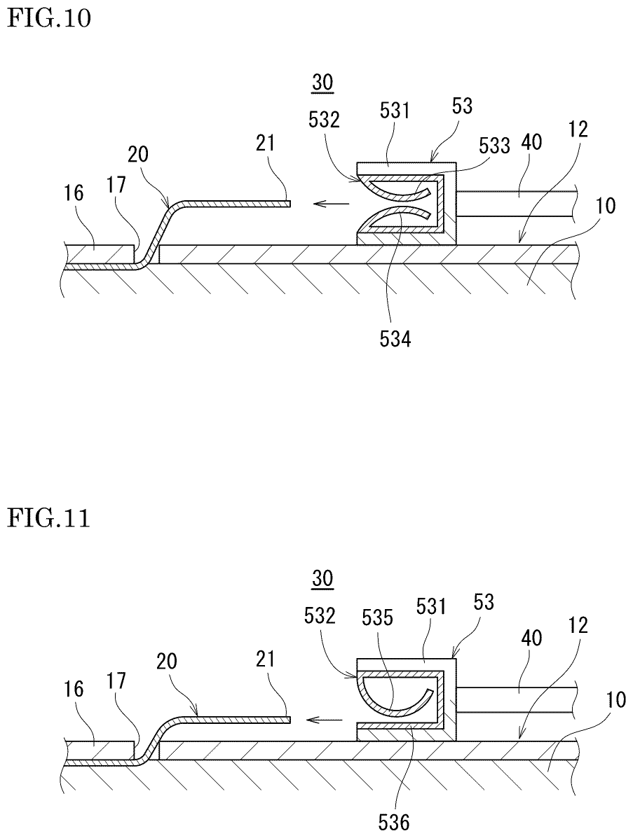

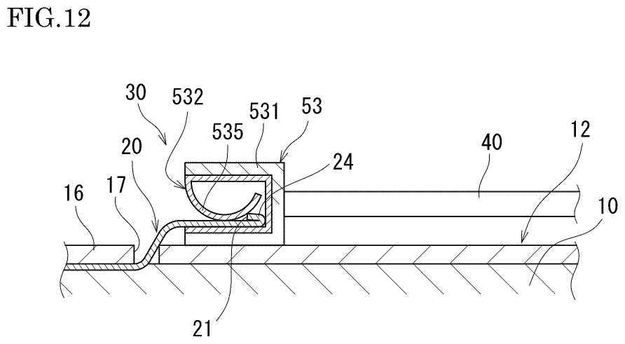

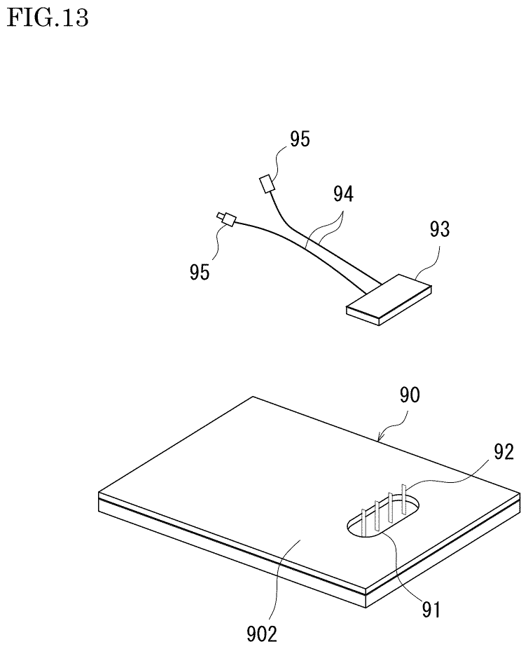

FIG. 10 is a sectional view of an output line connection structure for a solar cell module according to Embodiment 5 of the present disclosure, shown with a structure of a connection terminal 53 of the external connection cable 40. FIG. 11 is a sectional view showing another example of the connection terminal 53 of the external connection cable 40. FIG. 12 is a sectional view showing the output lead 20 connected to the connection terminal 53 shown in FIG. 11.

As shown in FIG. 10, the connection terminal 53 of the external connection cable 40 has a tubular holder part 531 made of an insulating material such as a resin, and an elastically deformable, elastic contact piece 532 provided inside the holder part 531. The elastic contact piece 532 is a metallic terminal connected to a core (not shown) of the external connection cable 40. The elastic contact piece 532 is configured to hold the extreme end 21 of the output lead 20 in a pinched manner by its elastic force.

In the configuration shown in FIG. 10, the elastic contact piece 532 has an upper piece 533 and a lower piece 534, the upper and lower pieces being leaf spring-like curved pieces and opposed vertically to each other. A gap (clearance) between the downwardly curved upper piece 533 and the upwardly curved lower piece 534 is not greater than the thickness of the output lead 20.

From the state shown in FIG. 10, the holder part 531 of the external connection cable 40 is brought toward the extreme end 21 of the output lead 20, until the extreme end 21 is inserted between the upper piece 533 and the lower piece 534 of the elastic contact piece 532. In the connection terminal 53, the output lead 20 is held in a pinched manner between the upper piece 533 and the lower piece 534 of the elastic contact piece 532, and thus is connected with the external connection cable 40.

In the elastic contact piece 532 above, both of the upper piece 533 and the lower piece 534 are elastically deformable. Instead, as shown in FIG. 11, either of the upper piece or the lower piece may be elastically deformable inside the holder part 531. In FIG. 11, the elastic contact piece 532 of the holder part 531 has a leaf spring-like, downwardly curved upper piece 535 and a flat plate-like lower piece 536. The elastic contact piece 532 can hold, by its elastic force, the extreme end 21 of the output lead 20 in a pinched manner between the upper piece 535 and the lower piece 536.

Further as shown in FIG. 12, the output lead 20 may be configured to have a bent portion 24 that is a portion of the extreme end 21 turned back toward the through-hole 17. In this case, the bent portion 24 is engaged with the upper piece 535 of the elastic contact piece 532 to prevent the output lead 20 from slipping out.

According to the above output line connection structure for the solar cell module 10, this configuration can also connect the output leads 20 to the terminal box, not directly but via the external connection cables 40. As a result, this configuration allows free setting of the terminal box without meticulous positioning, saves the space, and enables a quick connection operation. Irrespective of the types of electronic devices on which the solar cell module is installed, this configuration can apply the common solar cell module structure up to the output leads 20, and can thereby reduce the production cost. When the external connection cables 40 are connected to the terminal box containing the bypass diodes, this configuration can use the above-mentioned electric cables as the external connection cables to be led out from the terminal box, thereby facilitating the connection with an electronic device. As for the output extracted from the output leads 20 via the external connection cables 40, the voltage may be converted by a power converter such as a DC/DC converter, charged to a battery or the like, and used as a power source. This configuration can omit the terminal box and can reduce both the installation space and the cost.

The above-described embodiments are considered in all respects as illustrative and not restrictive. Therefore, the technical scope of the present invention should not be construed only by the foregoing embodiments but should be defined by the appended claims. All variations and modifications falling within the equivalency range of the appended claims are intended to be embraced therein.

The present application claims priority under Japanese Patent Application No. 2022-144526, filed on Sep. 12, 2022, the contents of which are incorporated herein by reference in its entirety.

### REFERENCE SIGNS LIST

10 solar cell module
11 light-receiving surface
12 back surface
13 solar cell
14 relay wiring member
15a, 15b, 15c, 15d output wiring member
16 back sheet
17 through-hole
20 output lead (output line)
21 extreme end
22 tapered portion
23 connection hole
24 bent portion
30 connecting portion
40 external connection cable
51, 52, 53 connection terminal
511, 521, 531 holder part
512, 522 fixing part
532 elastic contact piece
533, 535 upper piece
534, 536 lower piece
60 terminal box
61 bypass diode
62 external output cable

1. An output line connection structure for a solar cell module, for connecting an output line that extends out of the solar cell module, with an external connection cable, wherein
the solar cell module comprises at least one solar cell string in which a plurality of solar cells is connected in series with each other,
the output line is provided correspondingly to the solar cell string and is drawn out from a back surface of the solar cell module, the back surface being a surface opposite to a light-receiving surface of the solar cell module,
the external connection cable has a connecting end to be connected to the output line and comprises a connection terminal at the connecting end, the connection terminal being provided with a holder part into which the output line is inserted, and
a connecting portion for the holder part and an extreme end of the output line is provided on a back surface side of the solar cell module, the external connection cable is arranged on the back surface side of the solar cell module and has a second end that is an end opposite to the connecting end of the external connection cable, and the second end of the external connection cable is connected to an external electronic device or a terminal box.

2. The output line connection structure for a solar cell module according to claim 1, wherein
the output line is a band-like conductor plate, and
the holder part has a tubular shape with a clearance, and the extreme end of the output line is inserted in and crimped on the holder part.

3. The output line connection structure for a solar cell module according to claim 2, wherein
the output line has a tapered portion narrowing toward the extreme end.

4. The output line connection structure for a solar cell module according to claim 1, wherein
the holder part has a tubular shape with a clearance,
the extreme end of the output line has a tubular shape narrowing toward an extremity thereof and insertable in the holder part, and
the extreme end of the output line is inserted in and crimped on the holder part.

5. The output line connection structure for a solar cell module according to claim 1, further comprising
an elastic contact piece provided inside the holder part and configured to hold the output line in a pinched manner.

6. The output line connection structure for a solar cell module according to claim 5, wherein
the output line comprises a bent portion that is a turned-back portion of the extreme end, and the bent portion is engaged with the elastic contact piece.

7. The output line connection structure for a solar cell module according to claim 1, wherein
the solar cell string comprises a plurality of groups of solar cells in each of which a plurality of solar cells adjacent in a first direction is connected in series with each other, and an output wiring member that connects ends of the groups of solar cells is provided along a second direction that is orthogonal to the first direction, and
an end of the output wiring member is drawn out to the back surface side, either along the first direction or along the second direction, to serve as the output line.
